(19) United States
(12) Patent Application Publication
(10) Pub. No.: US 2007/0102815 A1
(43) Pub. Date: May 10, 2007

(54) Bumping process with self-aligned A1-cap and the elimination of 2nd passivation layer

(76) Inventors: Matthew Vernon Kaufmann, Morgan Hill, CA (US); Ray Huang, San Jose, CA (US); Vincent (Ming) Chen, Newport Beach, CA (US)

Correspondence Address: GARLICK HARRISON & MARKISON, P.O. BOX 160727, AUSTIN, TX, 78716-0727, US

(21) Appl. No.: 11/269,455

(22) Filed: Nov. 8, 2005

(51) Int. Cl. H01L 23/48; H01L 21/44

(52) U.S. Cl. 257/737; 438/108; 438/612; 438/614; 438/615; 257/778; 257/779

(57) ABSTRACT

The present invention provides a simplified process end flow for a flip chip device. This process flow, beginning with the deposition of a final metal layer for the IC, also includes the deposition of the UBM layer on top of the metal layer. The UBM layer and IC final metal layer are simultaneously patterned. This ensures alignment between the IC final metal layer and the UBM layer patterning and reduces processing steps. Such a process flow may eliminate the need for a second passivation deposition and patterning and the process of individually patterning the final metal layer.

### TECHNICAL FIELD OF THE INVENTION

The present invention relates generally to fabrication of integrated circuits, and more particularly to the deposition of bump materials within the manufacturing of flip chips.

### BACKGROUND OF THE INVENTION

Integrated circuits (IC) are increasing in complexity. The number of devices incorporated within a single IC is greatly increasing and causing the size and complexity of individual ICs to increase. As a result of increased component density and improved fabrication technology is the realization of system on chip (SoC) applications. Such a system on a chip may include many logic and memory functions within it. For example, the core may include a CPU core, DSP core, DSP book, memory, control circuitry and analog/mixed signal circuitry. These are just examples of the types of systems or components that may be integrated into a signal chip.

Complexities are associated with the realization of SoC designs. Incorporating diverse components previously contained within a single printed circuit board (PCB) involves confronting many design challenges. The components may be designed for different entities using different tools. Other difficulties lie in fabrication. In general, fabrication processes of memory may differ significantly from those associated with logic circuits. For example, speed may be the priority associated with a logic circuit while current leakage of the stored-charge is of priority for memory circuits. Therefore, multi-level interconnect schemes using five to six levels of metal are essential for logic ICs in order to offer improved speed, while memory circuits may need only two to three levels.

In order for the IC to be useful, the IC must have physical connections to the outside world. Two extremes in IC development support different types of interfaces to external devices. Low cost packaging which supports low pin count is achieved with traditional wire bond attached chips. High cost packaging may support high pin count in the case of flip chips. With wire bond attached chips I/O cells are placed at the edge of the die. Bond wire pads placed at the edge of the die outside I/O circuitry further increase the die size. 100051 Advances in device density within the core have made it possible to reduce core size of IC devices. However, reduced I/O pad-pitch (the pitch is typically defined as the repeat distance between adjacent I/O pads) has been hard to achieve because of packaging limitations. Therefore, as a result, IC designs that are I/O intensive tend to have a die size significantly greater than that of the core. This leads to poor utilization of the silicon area. Alternatively flip chip designs may be used for the I/O intensive applications.

Flip chip microelectronic assemblies contain direct electrical connections of face-down electronic components onto sub-straights or circuit boards by means of conductive bumps on IC bond pads. Thus, geometry allows more devices to be incorporated into a single IC. Flip chips offer advantages in size, performance, flexibility, reliability, and cost over other packaging methods. For example eliminating packages and bond wires greatly reduces the required board area by up to 95 percent and also requires far less height. Additionally, flip chips offer improved performance over other assembly methods as eliminating bond wires reduces the latency and capacitance associated with bond wires by significantly shortening the circuit path. This may result in high-speed off chip inner connects. The final metal layer of most IC bond pads is aluminum which provides a satisfactory surface for conventional wire bonding. However, this surface may be inhospitable to most conductive bumps as aluminum forms an oxide immediately upon exposure to air. The formation of wire bond scrubs the insulting oxide to weld with the underlying metal. Bumps on the other hand need an alternative strategy for making reliable electrical connections. Because aluminum is not a readily wettable surface, it may corrode over time if not protected from the environment. The bump on the bond pads typically requires an under-bump metallization (UBM) be placed on the chip bond pad in order to replace. Consequently, successful placement of a flip chip bump requires the removal of the oxidized aluminum surface and placement of a more hospitable material such as an under-bump metallization (UBM). Under-bump metallization generally requires multiple layers of different metals or conductive materials that form an adhesion layer, diffusion barrier layer, and an oxidation barrier layer. This addition of another metal layer typically requires an additional deposition and patterning process. Additional passivation layers may also be required.

FIG. 2 illustrates the results of a series of end process flows for a typical flip chip device. FIG. 1 provides a cross-section of a stack of the end processes associated with a flip chip device 10. These end processes result in metal layers 12 and 14. Metal layer 12 may be a metal layer such as copper or other like metal layer, while top layer 14 may be aluminum cap. Aluminum caps are often chosen because they provide a satisfactory surface for conventional wire bonding. However, aluminum is not a hospitable surface for solder bumps or conductive bumps 20. Aluminum forms a native oxide immediately upon exposure to atmosphere, which serves as an insulating layer. Additionally, aluminum may not provide a wettable surface on which solder reflow may be supported. Metallization layers 12 and 14 may be protected by protective layers such as passivation layers 16 and 18. These passivation layers may take the form of nitride passivation, polyimide layer, or other like materials. On top of patterned aluminum layer 14, UBM layer 22 is required to provide an adhesion layer, diffusion layer, and surface that is operable to support solder reflow. Thus, the use of a flip chip device adds at least one metallization layer and associated deposition and patterning. Each additional processing step within the semiconductor fabrication process increases the chances for defectivity and reduced yield.

### SUMMARY OF THE INVENTION

Embodiments of the present invention are directed to systems and methods that are further described in the following description and claims. Advantages and features of embodiments of the present invention may become apparent from the description, accompanying drawings and claims.

### BRIEF DESCRIPTION OF THE DRAWINGS

For a more complete understanding of the present invention and the advantages thereof, reference is now made to the following description taken in conjunction with the accompanying drawings in which like reference numerals indicate like features and wherein:

FIG. 1 provides a cross-section of the upper layers of a flip chip device;

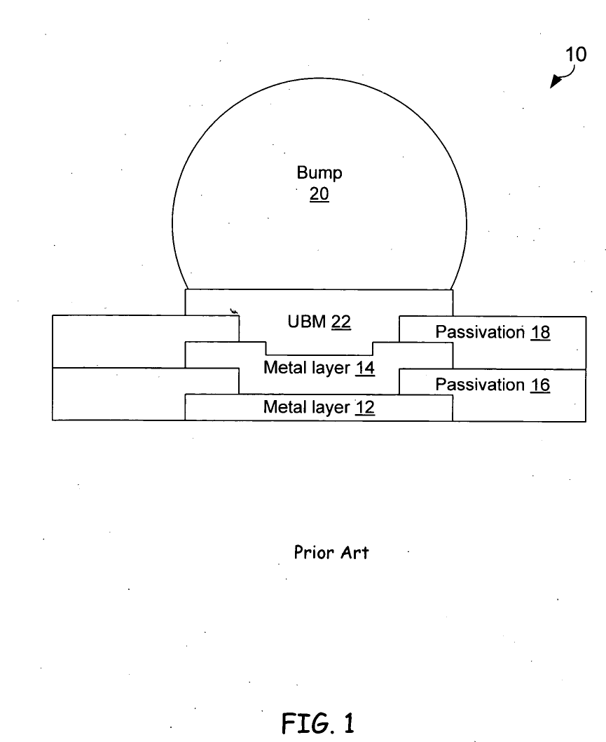

FIG. 2 provides a logic flow diagram illustrating the processes associated with the fabrication of a flip chip device;

FIG. 3A provides a streamlined process flow diagram associated with the fabrication of a flip chip device in accordance with an embodiment of the present invention;

FIG. 3B provides a second streamlined process flow diagram associated with the processing of a flip chip device in accordance with an embodiment of the present invention;

FIG. 4A provides a cross-section of the upper layers of a flip chip device fabricated using the processes discussed in FIG. 3A in accordance with an embodiment of the present invention;

FIG. 4B provides a cross-section of the upper layers of a flip chip device processed in accordance with the process flow. presented in FIG. 3B in accordance with an embodiment of the present invention;

FIG. 5 provides a process flow diagram associated with the manufacture of the upper layer of a flip chip device in accordance with an embodiment of the present invention; and

FIG. 6 provides a scanning electron micrograph (SEM) depicting the reflow of a eutectic bump that protects the sidewalls of UBM material as may be utilized in accordance with embodiments of the present invention.

### DETAILED DESCRIPTION OF THE INVENTION

Preferred embodiments of the present invention are illustrated in the FIGURES, like numerals being used to refer to like and corresponding parts of the various drawings.

The present invention provides a process end flow for a flip chip device that simplifies the end process flow for flip chip devices when compared to existing processes. This process flow, beginning with the deposition of a final metal layer for the IC, also includes the deposition of the UBM layer on top of the metal layer and then the simultaneous patterning of the UBM layer and IC final metal layer, wherein the IC final metal layer is patterned with and automatically aligned to the UBM layer patterning. Such a process flow may eliminate the need for second passivation deposition and patterning, and individually patterning the final metal layer and UBM layer. Removing these steps has the potential to simplify processing, reduce defects and increase yield.

Flip Chip devices utilize direct interconnections in which the IC is mounted upside down onto a modular or printed circuit board. Electrical connections are made via solder bumps or solderless materials such as epoxies or conductive adhesives located over the surfaces of the chip. Since the bumps can be located anywhere on the chip, front chip bonding ensures that the interconnect distance between the chip and package is minimized. The IO density is limited only by the minimum distance between adjacent bond pads.

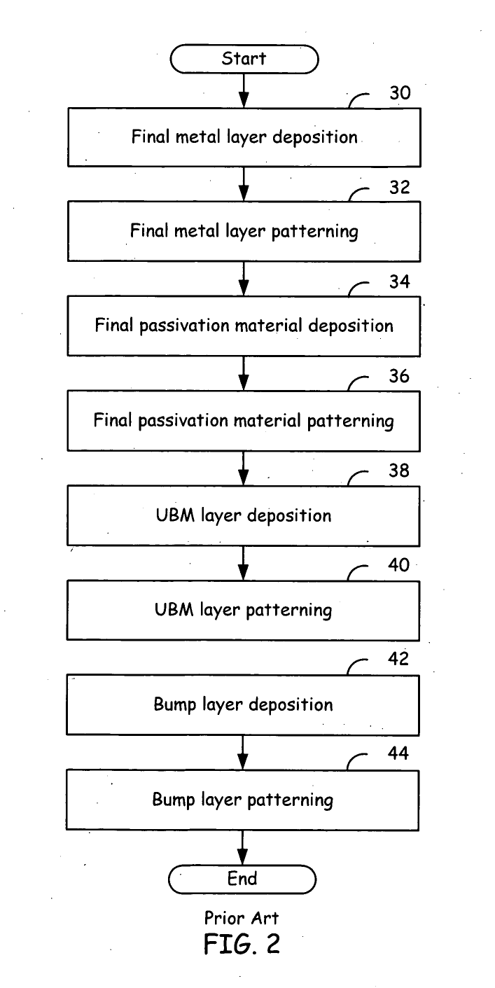

A typical end process flow for a flip chip device is illustrated in the process flow diagram provided in FIG. 2. In step 30, the final metal layer, such as an aluminum cap layer, is deposited. This aluminum cap is patterned in step 32. Because aluminum may be susceptible to corrosion or oxidation by exposure to the environment, a second passivation material, such as a nitride or polyimide, is deposited in step 34. This passivation material is then patterned in step 36.

The bumping sites on the bond pads of the IC are then prepared for bump. This preparation may include cleaning, removing insulating oxides, and providing a pad metallurgy that will protect the IC while making a good mechanical and electrical connection to the solder bump.

On top of the prepared IC, a UBM layer, which may constitute a stack of metals or conductive materials, is deposited in step 38. The UBM may overlap and protect exposed final metal layer circuitry from corrosion. UBM generally consists of successive layers of metal with functions described by their-names. The “adhesion layer” must adhere well to the bond pad metal (final metal layer) and the surrounding passivation, providing a strong, low-stress mechanical and electrical connection. The “diffusion barrier” layer limits the diffusion of solder into the underlying material. The “solder wettable.” layer offers a wettable surface to the molten solder during assembly, for good bonding of the solder to the underlying metal. A “protective layer” may be required to prevent oxidation of the underlying layer. This UBM layer is patterned in step 40.

Bump material will be deposited in step 42. Although eutectic Sn/Pb and high Pb alloys are the most prevalent bump materials used today, several new alloys are being introduced to the market that include Pb-free systems. Bumps may be formed or placed on the UBM in many ways, including evaporation, electroplating, printing, jetting, stud bumping, and direct. placement. The results of these methods may differ in bump size and spacing (“pitch”), solder components and composition, cost, manufacturing time, equipment required, assembly temperature, and UBM. The bump material is patterned in step 44. In order to form the eutectic solder bump, a reflow process may be performed in step 46.

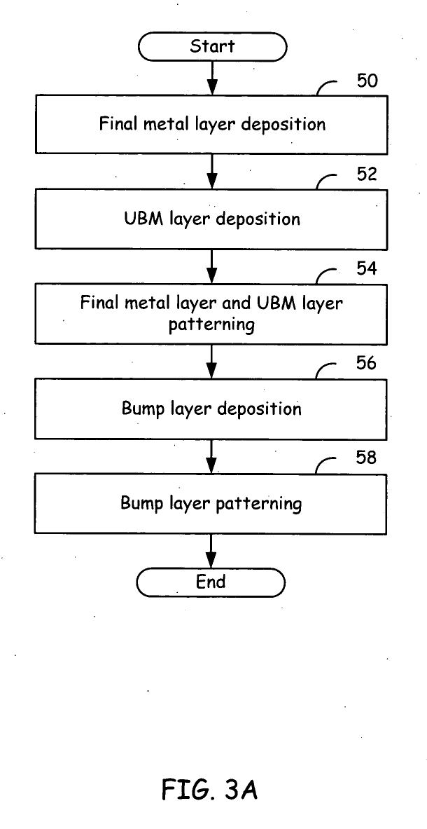

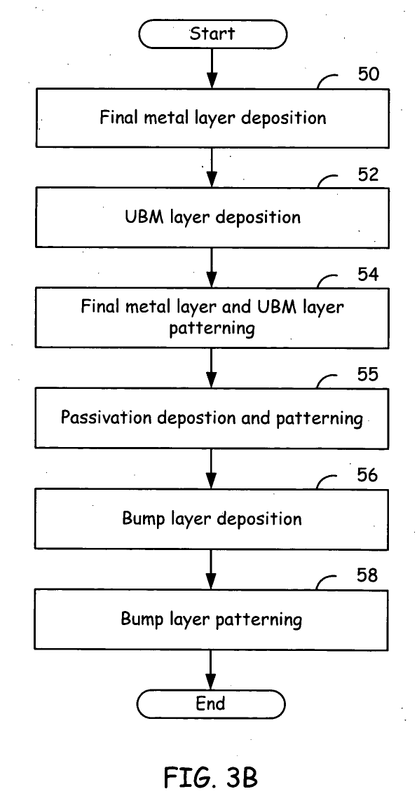

By selecting a proper etch process able to selectively etch both the UBM layer and the final metal layer, these materials may be etched and patterned in a single step. Such processing eliminates the potential for misalignment by automatically aligning the UBM to final metal layer. This allows the process of individually patterning the final metal layer, as well as depositing and patterning a second passivation layer to be eliminated. FIGS. 3A and 3B provide a logic flow diagram illustrating such a process. The process of FIGS. 3A and 3B lack steps 32, 34 and 36. Simplifying the process flow by removing steps may result in improved yields.

The etch process may be a dry etching method used to achieve high fidelity pattern transfers. This etch may rely on selectivity to avoid significantly etching dielectric layers beneath the removed metal layers. Alternatively, the etch process may rely on accurate end point detection to stop the etching process.

FIG. 3A provides a process flow diagram illustrating the end-process flow for a flip chip device in accordance with an embodiment of the present invention. Here, final metal layer deposition occurs in step 50 and is followed immediately by UBM layer deposition in Step 52. Step 54 patterns both the UBM layer and the final metal layer. This may be done by choosing an appropriate photo and etch processes such that the etch will properly pattern both the UBM layer and the final metal layer. As previously stated, this process eliminates the needs for steps 32, 34 and 36 shown in FIG. 2. After the final metal layer and UBM layer have been patterned, the bump material is deposited in step 56 and patterned in step 58.

FIG. 3B provides a logic flow diagram substantially similar to the logic flow diagram provided in FIG. 3A. However, the logic flow diagram of FIG. 3B includes an additional passivation step wherein passivation is deposited and patterned in step 55 following the final metal layer and UBM layer patterning of step 54, and prior to the deposition of bump material in step 56. This passivation layer may serve to protect potentially exposed portions of the final metal layer and UBM material from exposure to the environment.

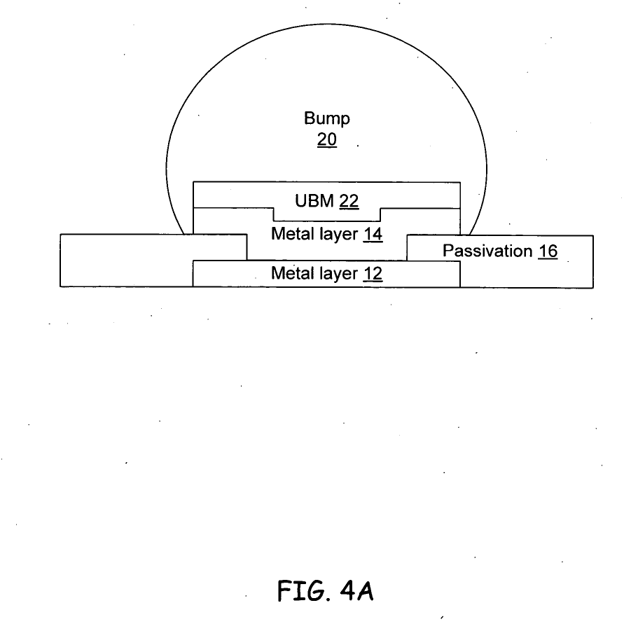

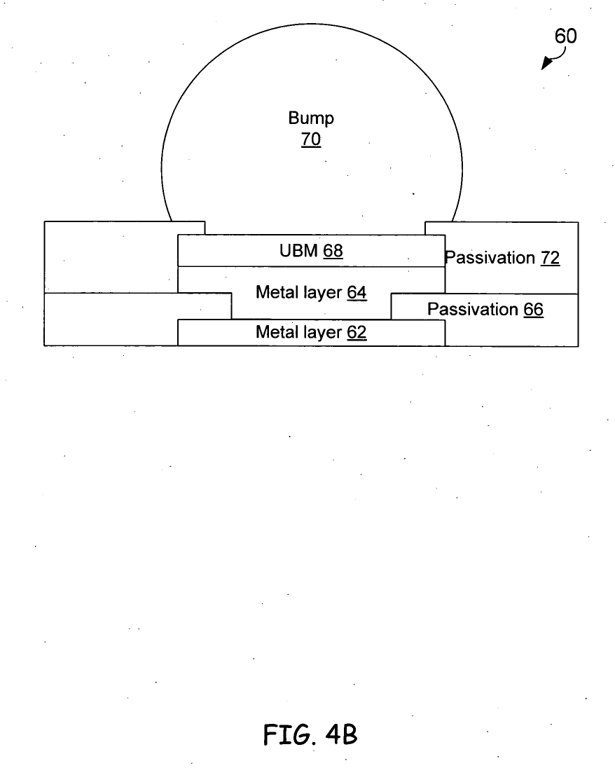

FIG. 4A provides a cross-section of the final layers of the flip chip device fabricated using the processes as described in FIG. 3A. Here, flip chip device 60 has metal layers 62 and 64. Prior to the deposition of metal layer 64, which may be an aluminum cap, passivation layer 66 is deposited and patterned on top of metal layer 62. UBM layer 68 is shown aligned to final metal layer 64. Additionally, eutectic bump 70 may cover the entire UBM layer concealing the UBM layer and final metal layer from exposure to the environment. As shown, this protection extends to the final metal layer 64 which may be aluminum. The eutectic bump conceals both the side walls of patterned UBM layer 68 and final metal layer 64. Such protection from the environment may remove the need for a second passivation as the top metal layer of aluminum is protected from corrosion and oxidation by the bump material. Removing processing steps decreases the likelihood of defects during the fabrication process, decreases processing time, and hence may result in improved product yields with simpler process flows. Further, by using a single patterning process, the alignment of the final metal layer and UBM is assured.

FIG. 4B provides a cross-section of the final layers of a flip chip device fabricated using the processes described in FIG. 3B. As shown here, an additional passivation layer 72 may protect potentially exposed portions of UBM layer 68 and metal layer 64. Specifically as shown here, passivation layer 72 may protect the side walls of UBM layer 68 and metal layer 64. In other embodiments, this additional layer of passivation may be replaced with passivation deposited as a spacer along the sidewalls of the metal layers.

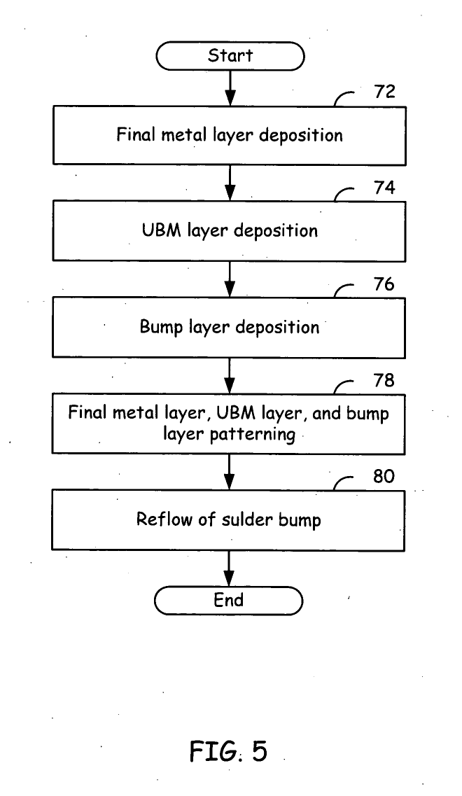

FIG. 5 provides yet another embodiment of the present invention where the end process flows are further simplified. In this process flow the final metal layer, UBM layer, and bump layer patterning are consolidated as a single step. Thus, in step 72, the final metal layer is deposited. Upon which the UBM layer is deposited on-top of the final metal layer in step 74. The bump layer is deposited on the blanket UBM layer and final metal layer in step 76. The patterning process of step 78 simultaneously patterns the final metal layer, UBM layer, and bump layer. This eliminates processing steps, reduces the possibility of miss processing and improves alignment. The solder bump may be re-flowed in step 80 in order to ensure that the side walls of the final metal layer and UBM layer are concealed and protected from corrosion and oxidization.

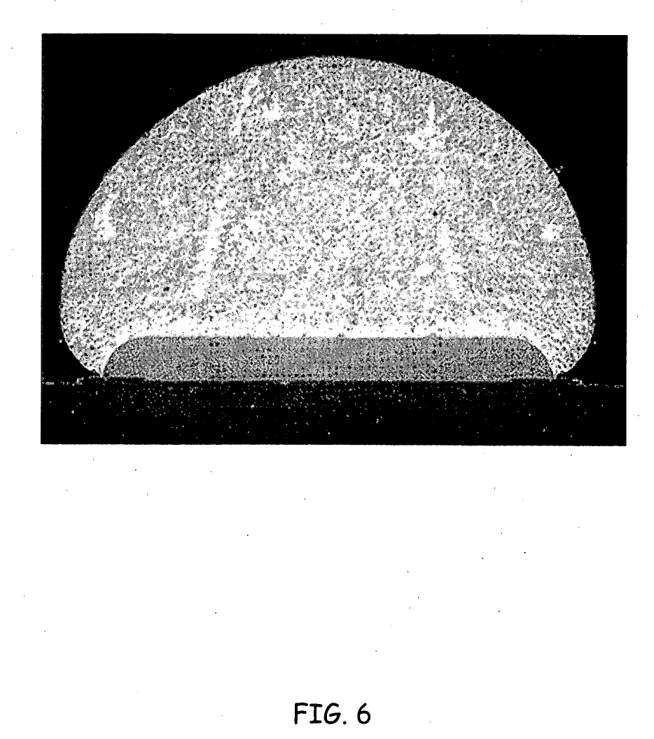

FIG. 6 provides a scanning election micrograph cross-section of an actual solder bump 82 that conceals the side walls of UBM layer 84. Bumps normally entirely covers the UBM, concealing and protecting the UBM. Thus, both the UBM and final metal layer are protected by the bump process.

In summary, embodiments of the present invention provide a process end flow for a flip chip device that simplifies the end process flow for flip chip devices. This process flow, beginning with the deposition of a final metal layer for the IC. The deposition of the UBM layer follows on top of the metal layer. Then, the simultaneous patterning of the UBM layer and IC final metal layer is contemplated, wherein the IC final metal layer is patterned with and automatically aligned to the UBM layer patterning. Such a process flow may eliminate the need for a second passivation deposition and patterning and the process of individually patterning the final metal layer.

Simplifying the process flow by removing steps may increase processing throughput, decrease processing time and potentially result in improved yields. These improved yields may arise from decreased defectivity. Additionally, by etching the UBM and final metal layer together, potential alignment errors are eliminated.

As one of average skill in the art will appreciate, the term “substantially” or “approximately”, as may be used herein, provides an industry-accepted tolerance to its corresponding term. Such an industry-accepted tolerance ranges from less than one percent to twenty percent and corresponds to, but is not limited to, component values, integrated circuit process variations, temperature variations, rise and fall times, and/or thermal noise. As one of average skill in the art will further appreciate, the term “operably coupled”, as may be used herein, includes direct coupling and indirect coupling via another component, element, circuit, or module where, for indirect coupling, the intervening component, element, circuit, or module does not modify the information of a signal but may adjust its current level, voltage level, and/or power level. As one of average skill in the art will also appreciate, inferred coupling (i.e., where one element is coupled to another element by inference) includes direct and indirect coupling between two elements in the same manner as “operably coupled”. As one of average skill in the art will further appreciate, the term “compares favorably”, as may be used herein, indicates that a comparison between two or more elements, items, signals, etc., provides a desired relationship. For example, when the desired relationship is that signal 1 has a greater magnitude than signal 2, a favorable comparison may be achieved when the magnitude of signal 1 is greater than that of signal 2 or when the magnitude of signal 2 is less than that of signal 1.

Although the present invention is described in detail, it should be understood that various changes, substitutions and alterations can be made hereto without departing from the spirit and scope of the invention as described by the appended claims.

What is claimed is:

1. A method, comprising:
depositing an integrated circuit (IC) final metal layer;
depositing an under-bump metallization (UBM) layer on top of the IC final metal layer; and
patterning the UBM layer, wherein the IC final metal layer is patterned with and automatically aligned to the UBM layer patterning.

2. The method of claim 1, further comprising:
depositing a bump material layer; and
patterning the bump material layer.

3. The method of claim 2, further comprising:
reflowing the patterned bump material layer to form a eutectic bump.

4. The method of claim 1, wherein the IC final metal layer is an aluminum metal layer.

5. The method of claim 1, wherein patterning the UBM layer further comprises:
applying a photolithic pattern on top of the UBM layer; and
etching the UBM layer and IC final metal-layer using the photolithic pattern.

6. The method of claim 1, wherein patterning the UBM layer further comprises:
applying a photolithic pattern on top of the UBM layer; and
etching the UBM layer with a first etch process using the photolithic pattern; and
etching the IC final metal layer with a second etch process using the photolithic pattern.

7. The method of claim 1, wherein the UBM layer, IC final metal layer and bump material are lead free compatible.

8. The method of claim 1, wherein the IC comprises a flip chip.

9. A method, comprising:
depositing an integrated circuit (IC) final metal layer;
depositing an under-bump metallization. (UBM) layer on top of the IC final metal layer;
depositing a bump layer on top of the UBM layer; and
patterning the bump layer, wherein the UBM layer and IC final metal layer is patterned with and automatically aligned to the bump layer.

10. The method of claim 9, further comprising:
reflowing the patterned bump material layer to form a eutectic bump.

11. The method of claim 9, further comprising:
reflowing the patterned bump material layer to form a eutectic bump at-a temperature of at least about 260° C.

12. The method of claim 9, wherein the IC final metal layer is an aluminum metal layer.

13. The method of claim 9, wherein patterning the bump layer further comprises:
applying a photolithic pattern on top of the bump layer; and
etching the bump layer, UBM layer and IC final metal layer using the photolithic pattern.

14. The method of claim 9, wherein patterning the UBM layer further comprises:
applying a photolithic pattern on top of the bump layer; and
etching the bump layer with a first etch process using the photolithic pattern;
etching the UBM layer with a second etch process using the photolithic pattern; and
etching the IC final metal layer with a third etch process using the photolithic pattern.

15. The method of claim 9, wherein the UBM layer, IC final metal layer and bump material are lead free compatible.

16. The method of claim 9, wherein the IC comprises a flip chip.

17. An integrated circuit (IC), comprising:
a top layer of patterned metal;
an under-bump metallization (UBM) patterned layer on top of and electrically coupled to the top layer of patterned metal, wherein the top layer of patterned metal is automatically aligned with the UBM patterned layer; and
a bump patterned layer on top of and electrically coupled to the UBM patterned layer,
wherein the top layer of patterned metal, UBM patterned later and bump patterned layer form a stack operable to electrically couple the IC to external circuits.

18. The IC of claim 17, wherein the top layer of patterned metal and UBM patterned layer automatically align to the bump patterned layer.

19. The IC of claim 17, wherein the bump patterned layer is reflowed at a temperature of at least about 260° C. to form a eutectic bump.

20. The IC of claim 17, wherein the top layer of patterned metal layer is an aluminum metal layer.

21. The IC of claim 17, wherein the top layer of patterned metal layer, UBM patterned layer and bump patterned layer are lead free compatible.

22. The IC of claim 17, wherein the IC comprises a flip chip.
